(19) United States
(12) Patent Application Publication
(10) Pub. No.: US 2024/0315149 A1
(43) Pub. Date: Sep. 19, 2024

(54) CRYOGENIC INTEGRATED CIRCUIT WITH A RESONATOR FORMED BY SUPERCONDUCTING METAL

(71) Applicant: International Business Machines Corporation, Armonk, NY (US)

(72) Inventors: Andrea Ruffino, Zuerich (CH); Mridula Prathapan, Adliswil (CH); Peter Mueller, Zurich (CH); John Francis Bulzacchelli, Somers, NY (US); Sudipto Chakraborty, Plano, TX (US); Thomas Morf, Gross (CH)

(21) Appl. No.: 18/183,200

(22) Filed: Mar. 14, 2023

(51) Int. Cl. H10N 69/00; G06N 10/40; H01L 29/66; H01P 3/08; H01P 7/08; H10N 60/85

(52) U.S. Cl. CPC H10N 69/00; G06N 10/40; H01L 29/66977; H01P 3/08; H01P 7/08; H10N 60/85

(57) ABSTRACT

The present disclosure relates to a cryogenic integrated circuit, the circuit being a Complementary metal-oxide-semiconductor (CMOS) or Bipolar CMOS (BiCMOS) stacked circuit. The circuit comprises: a substrate, and a resonator formed on the substrate. The resonator comprises a meandered inductor formed in a specific metal layer of the stack, wherein the specific metal layer, when cooled below a critical temperature, becomes superconducting.

### BACKGROUND

The present invention relates to the field of electronic systems, and more specifically, to a cryogenic integrated circuit comprising a resonator formed from a superconducting material.

When in need of LC circuits, a number of inductors may be kept to a minimum, such that the value of said inductors and the number of turns are also limited to minimize the area occupied by the LC circuits and still obtain a decent quality factor. As frequency goes down, minimizing the above variables can become even more critical. Otherwise, active inductors may be synthesized for non-noise critical applications.

### SUMMARY

Various embodiments provide a cryogenic integrated circuit and a method as described by the subject matter of the independent claims. Advantageous embodiments are described in the dependent claims. Embodiments of the present invention can be freely combined with each other if they are not mutually exclusive.

In one aspect, the invention relates to a cryogenic integrated circuit, the circuit being a Complementary metal-oxide-semiconductor (CMOS) or Bipolar CMOS (BiCMOS) stacked circuit. The circuit comprises: a substrate, and a resonator formed on the substrate. The resonator comprises a meandered inductor formed in a specific metal layer of the stack, wherein the specific metal layer, when cooled below a critical temperature, becomes superconducting.

In one aspect the invention relates to a method comprising: providing a cryogenic integrated circuit comprising a resonator, the resonator comprising an inductor formed from a superconducting material wherein the resonator, when cooled below a critical temperature, becomes superconducting.

In one aspect, the invention relates to a method comprising: forming an inductor by a meandered strip of conductor in a first metal layer of a CMOS stack or BiCMOS stack, wherein the first metal layer becomes superconducting in a CMOS process or BiCMOS process; forming a capacitor in a second metal layer and third metal layer of the CMOS stack or BiCMOS stack; forming a resonator by connecting the capacitor and the inductor using a via between the first metal layer and the second metal layer and another via from the first metal layer to the third metal layer. The terms “first,” “second,” and “third” are used as labels for nouns that they precede, and do not imply any type of ordering (e.g., spatial, temporal, logical) unless explicitly defined as such.

In one aspect, the invention relates to a quantum system comprising a phase-locked loop (PLL) circuit, and a receiver and/or transmitter. The phase-locked loop circuit comprises the cryogenic integrated circuit being an oscillator, the oscillator comprising a superconducting resonator, wherein the phase-locked loop circuit is configured to provide a signal of the oscillator to the receiver for qubit readout and/or to the transmitter for qubit control.

### BRIEF DESCRIPTION OF THE DRAWINGS

In the following, embodiments of the invention are explained in greater detail, by way of example only, making reference to the drawings in which:

FIG. 1 is a diagram of a cryogenic integrated circuit in accordance with an example of the present subject matter.

FIG. 2 is a diagram illustrating a LC filter in accordance with an example of the present subject matter.

FIG. 3 is a diagram illustrating an LC oscillator in accordance with an example of the present subject matter.

FIG. 4 is a plot illustrating the resistance of metal resistor for various temperatures.

FIG. 5 is a flowchart of a method for forming a resonator in a cryogenic integrated circuit in accordance with an example of the present subject matter.

### DETAILED DESCRIPTION

The descriptions of the various embodiments of the present invention will be presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Inductors occupy most of the space in integrated circuits. For example, an inductor may occupy more than 100 μm² area, which severely limits the integration scale of such circuits.

A cryogenic integrated circuit may be provided. The cryogenic integrated circuit may comprise a substrate such as a semiconductor substrate. A resonator (RES) may be implemented on the substrate of the cryogenic integrated circuit. The resonator RES comprises an inductor implemented in a specific metal layer of a CMOS or BiCMOS stack, wherein the specific metal layer, when cooled below a critical temperature, becomes superconducting. The wiring of the inductor may be implemented in the specific metal layer. The inductor may be a kinetic inductor. The stack may refer to an arrangement of metal layers which may be used for building CMOS or BiCMOS based integrated circuits. The metal layers in a CMOS or BiCMOS integrated circuit may enable one to connect circuit elements such as capacitors and resistors. The number and type of metal layers of a stack may be defined based on the CMOS process or based on the BiCMOS process being used.

The present subject matter may make use of the predefined metal layers of the CMOS or BiCMOS process in order to implement the inductor in one metal layer of the stack, wherein the one metal layer, when cooled below a critical temperature, becomes superconducting. Vias to other layers may be used to connect the inductor to the rest of the circuit such as the transistor and the capacitor. For that, the inductor may be a meandered inductor or meander inductor. The meandered inductor may be realized by a meandered stripline. The meandered inductor may follow a single winding path, with the single winding path having two or more changes in direction. The meandered inductor may be advantageous as it may seamlessly be integrated in a single metal layer of the CMOS stack or BiCMOS stack. By contrast to a spiral inductor, the structure of the meandered inductor may not require multiple loops or require underpasses or overpasses to other layers.

For example, the resonator may be formed by an inductor and a capacitor. The inductor may be formed by a meandered strip of conductor implemented in a metal layer that becomes superconducting in the CMOS process. The metal layer may, for example, be a first metal layer of the CMOS stack just above the transistor layers of the CMOS stack. The capacitor may be formed by using another two normal conducting layers. The two conducting layers may, for example, be the second metal layer and third metal layer of the CMOS stack which are separated by the intermetal dielectric. This may enable one to form a metal-insulator-metal capacitor. A resonator may be formed by connecting the capacitor and the inductor. For that, vias may be used to connect the inductor and the capacitor in parallel. In particular, a via between the first metal layer and the second metal layer may be provided on one end of the inductor and a via between the first metal layer and the third metal layer may be provided on the other end of the inductor.

The present subject matter may enable compact circuits that can operate at a low temperature regime. The present circuit may be optimally used in applications of a field where cryogenic CMOS electronics is used, such as microwave electronics for quantum computing. timing circuits for low temperature detectors in high energy physics experiments and cryogenically cooled low noise instruments for radio astronomy. The present subject matter may establish a new class of cryogenic CMOS or BiCMOS circuits based on superconducting metal layers to realize low power and low noise oscillators.

According to one example, the cryogenic integrated circuit may comprise an LC oscillator. The LC oscillator comprises the resonator RES. The LC oscillator may further comprise a set of cross-coupled transistors. The LC oscillator is a CMOS oscillator or BiCMOS oscillator. The set of cross-coupled transistors may comprise two cross-coupled CMOS transistors or two cross-coupled heterojunction bipolar transistors (HBTs). A negative [symbol] ₘ may be presented by the two cross-coupled transistors. The cross coupled transistors may enable one to cancel the loss of the LC tank in order to sustain periodic oscillations at resonance. This may provide a low phase noise or low power LC oscillator.

Oscillators may be key components in analog devices. However, oscillators may dissipate significant amounts of power. In order to save power, the present subject matter may provide the oscillators with inductors made of superconducting materials. For example, if the resonator quality factor is very large, the negative [symbol] ₘ of the cross coupled pair required to sustain the oscillation may be much smaller, thus resulting in smaller power consumption. Also, if the resonator quality factor is very large, the phase noise of the oscillator can be greatly improved, thus yielding high-performance cryogenic oscillators. The quality factor, commonly expressed as the Q factor, may define a relation between the resonant circuit's capacity for electromagnetic storage with its energy dissipation through heat. Resonator bandwidth is inversely proportional to Q factor. Thus, high Q factor resonators have narrow bandwidths.

According to one example, the oscillator is configured to generate a high frequency signal in a frequency range of 1 GHz up to 20 GHz. Alternatively, the frequency range may be 4 GHz to 6 GHz. This may particularly be advantageous for quantum computing. Indeed, the qubit operation frequency may be typically around 5 GHZ which is provided by the present oscillator. The temperature regime of the cryogenic circuit may also be advantageous as the qubits may need to be operated at much lower temperatures. For example, the qubits may be kept in dilution fridges, together with the cryogenic circuit. This may enable one to operate the circuit elements controlling the qubits at extremely low (cryogenic) temperatures, so they can be placed as close as possible to the qubits. This may enable one to build large-scale quantum computers.

According to one example, the length of the inductor is provided such that the frequency of the signal generated by the oscillator is within a desired range. This may particularly be advantageous as the inductor according to the present subject matter may be flexibly adapted to provide the desired frequency range. For example, the length of the meandered wire is approximately proportional to the inductance (in the kinetic regime), since the material, for a given thickness, has a certain kinetic inductance per unit length. The inductance may thus be related to the frequency f of the signal generated by the oscillator according to f=1/(2π·sqrt(L·C)).

According to one example, the cryogenic integrated circuit is an oscillator of a phase-locked loop circuit. The phase-locked loop circuit is configured to provide a signal of the oscillator to a radio receiver for qubit readout and/or to a radio transmitter for qubit control. This may enable a seamless integration of the present subject matter in new quantum computing systems. It may provide the signals at desired frequencies in an efficiently implemented compact circuit. The present subject matter may realize compact phase locked loops with superior performance to be inserted in quantum processors for cryogenic signal generation and/or clock and data recovery. The applications of the present PLL may be in a field where cryogenic CMOS electronics is used, such as microwave electronics for quantum computing, timing circuits for low temperature detectors in high energy physics experiments and cryogenically cooled low noise instruments for radio astronomy.

According to one example, the resonator is an LC filter. The LC filter may provide a bandpass filter for frequency selection. Since the inductor is superconducting, the quality factor of the LC filter can be very large. Thus, the bandwidth can be very small and sharp bandpass selection filters can be realized with zero power consumption and small area. The present subject matter may enable sharp filters and high-performance oscillators in compact CMOS or BiCMOS chips for quantum processor readout and control. The applications of the present filters or oscillators may be in a field where cryogenic CMOS electronics is used, such as microwave electronics for quantum computing, timing circuits for low temperature detectors in high energy physics experiments and cryogenically cooled low noise instruments for radio astronomy.

The inductor may have a set of one or more properties. In one example, a property of the set of properties may be the width of the inductor, wherein the value, referred to as P1, of the width is in the range 1 μm-50 μm. In one example, a property of the set of properties may be the length of the inductor, wherein the value, referred to as P2, of the length is in the range 1 μm-50 μm. In one example, a property of the set of properties may be the number of meanders of the inductor, wherein the value, referred to as P3, of the number of meanders is in the range 2-100. In one example, a property of the set of properties may be the metal trace width of the inductor, wherein the value, referred to as P4, of the metal trace width is in the range 10 nm-200 nm. In one example, a property of the set of properties may be the meander spacing of the inductor, wherein the value, referred to as P5, of the meander spacing is in the range 10 nm-200 nm. In one example, a property of the set of properties may be the inductor value, referred to as P6, of the inductor which is in the range 20 pH-250 nH. This set of properties may enable one to control the size of the inductor, e.g., to provide a very small size inductor. The present subject matter may control values of the set of properties so that a right balance between an optimal area and large inductance can be achieved. For example, the properties values P1, P2, P4 and P5 may be used to control the area while the properties values P3 and P6 may be used to control the level of inductance. For example, the properties values P1 and P2 should be as small as possible to make the inductor small. The property value P3 should be large to have large inductance. The property value P4 should be as small as possible to reduce the area. The property value P5 should be also small to reduce the area. The property value P6 should be large to have large inductance.

According to one example, the metal layer in which the inductor is integrated comprises a superconducting material that is one of: Aluminium (Al), Tungsten Silicide (WSi), Niobium (Nb), Niobium Nitride (NbN), Titanium Nitride (TiN), Niobium Titanium Nitride (NbTiN) or another material which becomes superconductive.

According to one example, the metal layer in which the inductor is integrated comprises a superconducting material that is a mixture of two or more of: Aluminium (Al), Tungsten Silicide (WSi), Niobium (Nb), Niobium Nitride (NbN), Titanium Nitride (TiN), Niobium Titanium Nitride (NbTiN), or another material which becomes superconductive.

In the superconducting state, metal films may exhibit kinetic inductance from the Cooper pairs' frictionless movement. The present subject matter may enable a realization of cryogenic integrated circuits with resonators using inductors or transformers implemented in such a metal layer in (Bi)CMOS that becomes superconducting when operated below the critical temperature T_{c}. The critical temperature may, for example, be T_{c}˜1.2 K (kelvin) for Al and T_{c}˜9.2 K for Nb. This may yield compact area based on the kinetic inductance and yield a high-quality factor based on the low loss. This may further enable realization of cryogenic integrated circuits with said resonators to implement compact (exploiting kinetic inductance) low phase noise and low power (exploiting the low loss) LC oscillators in (Bi)CMOS processes using additional transistors for quantum or other low temperature applications.

In one example the superconducting material may be a mixture of Al and WSi. This mixture may be advantageous because it involves materials which are already present in advanced CMOS metal stacks.

In one example the superconducting material may be a mixture of Al and Nb.

In one example the superconducting material may be a mixture of Al and NbN.

In one example the superconducting material may be a mixture of Al and TiN.

In one example the superconducting material may be a mixture of Al and NbTiN.

In one example the superconducting material may be a mixture of WSi and Nb.

In one example the superconducting material may be a mixture of WSi and NbN.

In one example the superconducting material may be a mixture of WSi and TiN.

In one example the superconducting material may be a mixture of WSi and NbTiN.

In one example the superconducting material may be a mixture of Nb and NbN. Compared to other mixtures, this mixture may be advantageous because the materials have a critical temperature which is higher, thus allowing operation of the circuit e.g., at 4 K.

In one example the superconducting material may be a mixture of Nb and TiN.

In one example the superconducting material may be a mixture of Nb and NbTiN.

In one example the superconducting material may be a mixture of NbN and TiN.

In one example the superconducting material may be a mixture of NbN and NbTiN.

In one example the superconducting material may be a mixture of TiN and NbTiN.

According to one example, the substrate layer is provided with a field-effect transistor (FET), such as a fin field-effect transistor (FinFET), or a bipolar transistor, such as a heterojunction bipolar transistor (HBT) structure. Vias of the cryogenic integrated circuit may enable one to connect the inductor with the rest of the circuit such as with the transistors and the capacitor of the circuit.

According to one example, the superconducting material is one of the metal layers of a predefined CMOS node, or a predefined BiCMOS node. The CMOS (BiCMOS) node may be a process node that refers to a specific semiconductor manufacturing process and its design rules. Different nodes may imply different circuit generations and architectures. In one example, the CMOS node may be a 5 nm node, 7 nm node or 14 nm node. This may enable a seamless integration of the present subject matter with existing systems.

The present cryogenic (Bi)CMOS circuit based on a predefined process node may require being operated at temperatures below the critical temperature of the used superconducting material. This may be possible in dilution refrigerators for quantum computing as a corresponding temperature stage exists. The cryogenic electronics may be distributed across multiple stages based on power consumption and noise requirements. Hence, small area and high-performance filters and oscillators may be realized in accordance with the present subject matter in CMOS or BiCMOS at low temperature by exploiting layers in the metal stack, of the predefined process node, that become superconducting below e.g., 1 K, to implement superconducting inductors. This may create sharp selection filters and oscillators for use in cryogenic CMOS electronics for quantum computing, high energy physics experiments and other cryogenic applications.

In one example, the inductor may have the properties values: P1 and P2. In one example, the inductor may have the properties values: P1 and P3. In one example, the inductor may have the properties values: P1 and P4. In one example, the inductor may have the properties values: P1 and P5. In one example, the inductor may have the properties values: P1 and P6. In one example, the inductor may have the properties values: P2 and P3. In one example, the inductor may have the properties values: P2 and P4. In one example, the inductor may have the properties values: P2 and P5. In one example, the inductor may have the properties values: P2 and P6. In one example, the inductor may have the properties values: P3 and P4. In one example, the inductor may have the properties values: P3 and P5. In one example, the inductor may have the properties values: P3 and P6. In one example, the inductor may have the properties values: P4 and P5. In one example, the inductor may have the properties values: P4 and P6. In one example, the inductor may have the properties values: P5 and P6. In one example, the inductor may have the properties values: P1 and P2 and P3. In one example, the inductor may have the properties values: P1 and P2 and P4. In one example, the inductor may have the properties values: P1 and P2 and P5. In one example, the inductor may have the properties values: P1 and P2 and P6. In one example, the inductor may have the properties values: P1 and P3 and P4. In one example, the inductor may have the properties values: P1 and P3 and P5. In one example, the inductor may have the properties values: P1 and P3 and P6. In one example, the inductor may have the properties values: P1 and P4 and P5. In one example, the inductor may have the properties values: P1 and P4 and P6. In one example, the inductor may have the properties values: P1 and P5 and P6. In one example, the inductor may have the properties values: P2 and P3 and P4. In one example, the inductor may have the properties values: P2 and P3 and P5. In one example, the inductor may have the properties values: P2 and P3 and P6. In one example, the inductor may have the properties values: P2 and P4 and P5. In one example, the inductor may have the properties values: P2 and P4 and P6. In one example, the inductor may have the properties values: P2 and P5 and P6. In one example, the inductor may have the properties values: P3 and P4 and P5. In one example, the inductor may have the properties values: P3 and P4 and P6. In one example, the inductor may have the properties values: P3 and P5 and P6. In one example, the inductor may have the properties values: P4 and P5 and P6. In one example, the inductor may have the properties values: P1 and P2 and P3 and P4. In one example, the inductor may have the properties values: P1 and P2 and P3 and P5. In one example, the inductor may have the properties values: P1 and P2 and P3 and P6. In one example, the inductor may have the properties values: P1 and P2 and P4 and P5. In one example, the inductor may have the properties values: P1 and P2 and P4 and P6. In one example, the inductor may have the properties values: P1 and P2 and P5 and P6. In one example, the inductor may have the properties values: P1 and P3 and P4 and P5. In one example, the inductor may have the properties values: P1 and P3 and P4 and P6. In one example, the inductor may have the properties values: P1 and P3 and P5 and P6. In one example, the inductor may have the properties values: P1 and P4 and P5 and P6. In one example, the inductor may have the properties values: P2 and P3 and P4 and P5. In one example, the inductor may have the properties values: P2 and P3 and P4 and P6. In one example, the inductor may have the properties values: P2 and P3 and P5 and P6. In one example, the inductor may have the properties values: P2 and P4 and P5 and P6. In one example, the inductor may have the properties values: P3 and P4 and P5 and P6. In one example, the inductor may have the properties values: P1 and P2 and P3 and P4 and P5. In one example, the inductor may have the properties values: P1 and P2 and P3 and P4 and P6. In one example, the inductor may have the properties values: P1 and P2 and P3 and P5 and P6. In one example, the inductor may have the properties values: P1 and P2 and P4 and P5 and P6. In one example, the inductor may have the properties values: P1 and P3 and P4 and P5 and P6. In one example, the inductor may have the properties values: P2 and P3 and P4 and P5 and P6. In one example, the inductor may have the properties values: P1 and P2 and P3 and P4 and P5 and P6.

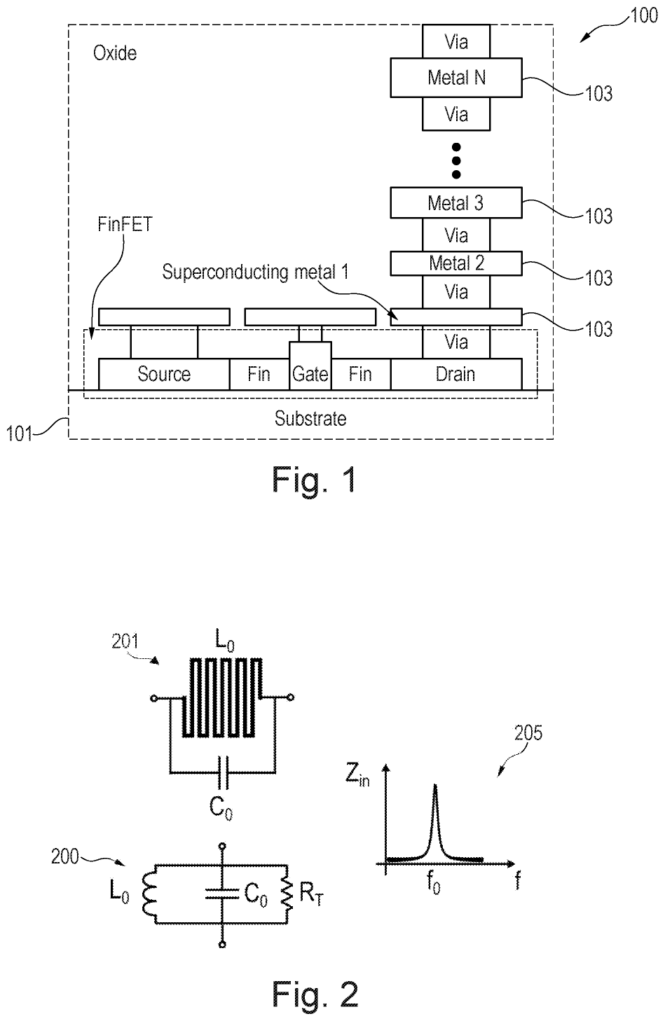

FIG. 1 depicts a cross section of a CMOS circuit with a resonator according to an example of the present subject matter.

The CMOS circuit 100 comprises a CMOS metal stack 103 and a substrate 101. The CMOS metal stack comprises a set of metal layers 103. The set of metal layers 103 comprises a number N of metal layers, wherein the metal 1 layer is a superconducting metal. The resonator may be formed by an inductor and a capacitor. The inductor of the resonator may be implemented in the metal 1 layer. Using the metal 1 layer may enable one to use compact inductors and thus realization of cryogenic integrated circuits e.g., with LC filters (resonators) using inductors or transformers implemented in the metal 1 layer that becomes superconducting when operated below the critical temperature. The second metal layer and third metal layer of the CMOS stack, which are separated by the intermetal dielectric, may be used to form a metal-insulator-metal capacitor. In order to connect the capacitor and the inductor, to form the resonator, two vias may be used. A via may be used between the first metal layer and the second metal layer on one end of the inductor and another via may be used between the first metal layer and the third metal layer on the other end. This may enable one to connect the inductor and the capacitor in parallel.

The substrate 101 is provided in accordance with a FET structure comprising field-effect transistors, such as FinFETs, or a bipolar structure comprising HBTs. As shown in FIG. 1, vias to other layers may be used to connect the inductor to the rest of the circuit e.g., including the transistor and the capacitor. For example, the inductor may be connected to the drain of the transistor.

The used metal 1 layer, such as Al or WSi layer, which can be already present in CMOS advanced nodes, may become superconducting below 1 K. This may enable one to realize small and high Q inductors. Alternatively, other materials could also be integrated in CMOS processes for operation above 4 K.

FIG. 2 depicts an LC filter 200 according to an example of the present subject matter. The LC filter 200 comprises an inductor 201 that is made of a superconducting material. For example, the inductor may be a Nb meander with a total length of 1=500 μm, an area of 10×10 μm², and a 22 nH inductance at 2.6 K, resulting in 44 nH/mm inductance per length. The LC filter 200 comprises a capacitance that is connected in parallel with the inductor 201. The resistor shown in the LC filter 200 may represent the loss due to the residual resistance from vias and other conductors.

FIG. 2 further illustrates a frequency response 205 for the LC filter 200. Zᵢₙ denotes the input impedance into the circuit. The bandpass response is characterized by a center frequency f₀. Since the inductor is superconducting, the quality factor of the LC filter can be very large. With the quality factor being very large, the bandwidth can be very small and sharp bandpass selection filters can be realized with zero static power consumption and small area.

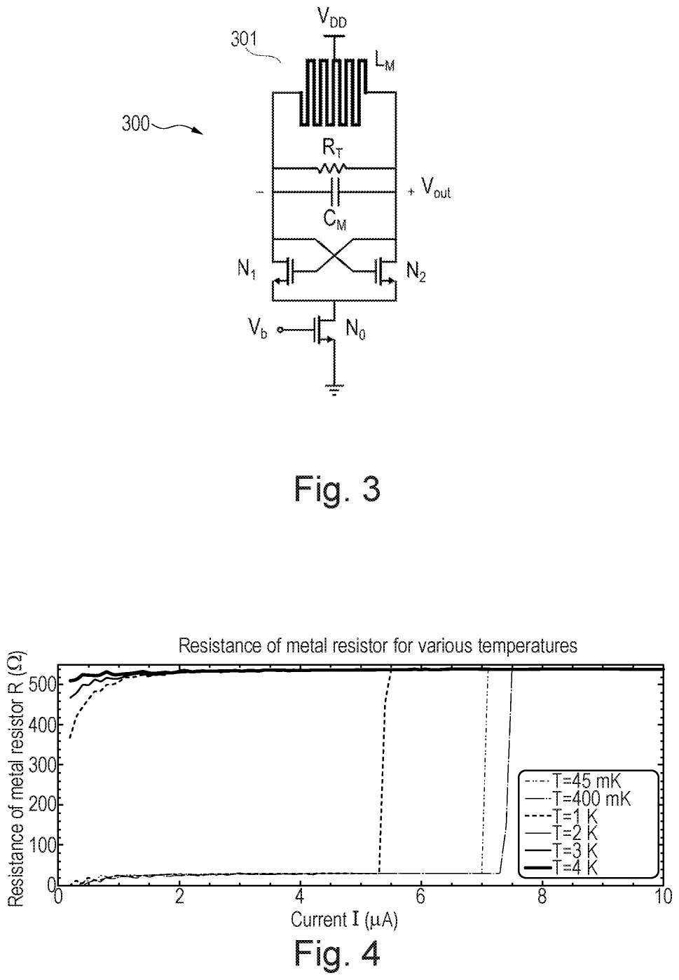

FIG. 3 depicts an equivalent circuit of an LC oscillator 300 according to an example of the present subject matter. The LC oscillator 300 comprises an LC-tank and cross coupled transistors. The LC tank may be modelled by a parallel RLC network. The LC tank comprises an inductor 301 that is made of a superconducting material. A negative [symbol] ₘ may be presented by the two cross-coupled transistors. The cross coupled transistors may enable one to cancel the loss of the LC tank in order to sustain periodic oscillations at resonance.

Since the inductor is superconducting, the quality factor of the LC filter can be very large. With the quality factor being very large in the LC oscillator 300, the negative [symbol] ₘ of the cross coupled pair required to sustain the oscillation may be much smaller, thus resulting in smaller power consumption. Also, since the resonator quality factor is very large, the phase noise of the oscillator 300 can be greatly improved, thus yielding high-performance cryogenic oscillators.

FIG. 4 is a plot illustrating the resistance of metal resistors in an advanced CMOS technology for various temperatures. The metal resistor may be a resistor including a metal layer of the CMOS process as a resistance component. Metal resistors become superconducting below 2 K, with the residual resistance only limited by via resistance. This indicates that the right materials could be already present in the CMOS stack.

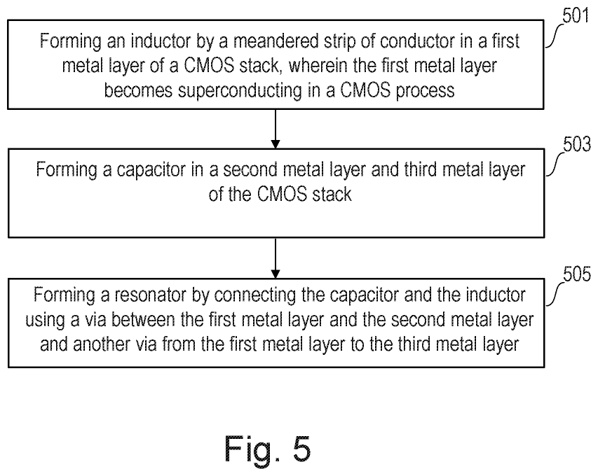

FIG. 5 is a flowchart of a method for forming a resonator in a cryogenic integrated circuit in accordance with an example of the present subject matter. In step 501, an inductor may be formed by a meandered strip of conductor in a first metal layer of a CMOS stack, wherein the first metal layer becomes superconducting in a CMOS process. A capacitor may be formed in step 503 in a second metal layer and third metal layer of the CMOS stack. A resonator may be formed in step 505 by connecting the capacitor and the inductor using a via between the first metal layer and the second metal layer and another via from the first metal layer to the third metal layer.

1. A cryogenic integrated circuit, the circuit being a Complementary metal-oxide-semiconductor (CMOS) or Bipolar CMOS (BiCMOS) stacked circuit, the circuit comprising:
a substrate, and
a resonator formed on the substrate, the resonator comprising a meandered inductor formed in a specific metal layer of the stack, wherein the specific metal layer, when cooled below a critical temperature, becomes superconducting.

2. The cryogenic integrated circuit of claim 1, wherein the resonator is an LC resonator of an oscillator comprising a set of transistors.

3. The cryogenic integrated circuit of claim 2, wherein the oscillator is configured to generate a high frequency signal in a frequency range of 1 GHz up to 20 GHz.

4. The cryogenic integrated circuit of claim 2, wherein dimensions of the inductor are provided such that the frequency of the signal generated by the oscillator is within a desired range.

5. The cryogenic integrated circuit of claim 1, wherein the circuit is an oscillator of a phase-locked loop circuit, the phase-locked loop circuit being configured to provide a signal of the oscillator to a radio receiver for qubit readout and/or to a radio transmitter for qubit control.

6. The cryogenic integrated circuit of claim 1, wherein the resonator is an LC filter.

7. The cryogenic integrated circuit of claim 1, wherein the inductor has a width ranging between 1 μm and 50 μm.

8. The cryogenic integrated circuit of claim 1, wherein the inductor has a length between 1 μm and 50 μm.

9. The cryogenic integrated circuit of claim 1, wherein the inductor has a number of meanders between 2 and 100.

10. The cryogenic integrated circuit of claim 1, wherein the inductor has a metal trace width between 10 nm and 200 nm.

11. The cryogenic integrated circuit of claim 1, wherein the inductor has a meander spacing between 10 nm and 200 nm.

12. The cryogenic integrated circuit of claim 1, wherein the inductor has an inductor value between 100 pH and 250 nH.

13. The cryogenic integrated circuit of claim 1, wherein the metal layer comprises a superconducting material that comprises at least one of: Aluminium (Al), Tungsten Silicide (WSi), Niobium (Nb), Niobium Nitride (NbN), Titanium Nitride (TiN), Niobium Titanium Nitride (NbTiN) or another material that becomes superconducting.

14. The cryogenic integrated circuit of claim 1, wherein the substrate layer is provided with a field-effect transistor (FET) or a heterojunction bipolar transistor (HBT) structure.

15. The cryogenic integrated circuit of claim 1, wherein the stack is defined according to a predefined CMOS node or BiCMOS node.

16. A quantum system comprising a phase-locked loop (PLL) circuit, and a receiver, the phase-locked loop circuit comprising a cryogenic integrated circuit, the circuit being a Complementary metal-oxide-semiconductor (CMOS) or Bipolar CMOS (BiCMOS) stacked circuit, the circuit comprising:
a substrate, and
a resonator formed on the substrate, the resonator comprising a meandered inductor formed in a specific metal layer of the stack, wherein the specific metal layer, when cooled below a critical temperature, becomes superconducting.

17. The quantum system of claim 16, wherein the phase-locked loop circuit is configured to provide a signal of the oscillator to the receiver for qubit readout.

18. The quantum system of claim 16, further comprising a transmitter.

19. The quantum system of claim 18, wherein the phase-locked loop circuit is configured to provide a signal of the oscillator to the transmitter for qubit control.

20. A method comprising:
forming an inductor by a meandered strip of conductor in a first metal layer of a CMOS stack or BiCMOS stack, wherein the first metal layer becomes superconducting in a CMOS process or BiCMOS process;
forming a capacitor in a second metal layer and third metal layer of the CMOS stack or BiCMOS stack; and
forming a resonator by connecting the capacitor and the inductor using a via between the first metal layer and the second metal layer and another via from the first metal layer to the third metal layer.
